(19) United States
(12) Patent Application Publication
(10) Pub. No.: US 2020/0029433 A1
(43) Pub. Date: Jan. 23, 2020

(54) SUBSTRATE STRUCTURE AND MANUFACTURING METHOD THEREOF

(71) Applicant: Unimicron Technology Corp., Taoyuan (TW)

(72) Inventors: Chien-Chen LIN, Taoyuan City (TW); Kuan-Wen FONG, Keelung City (TW)

(21) Appl. No.: 16/121,645

(22) Filed: Sep. 5, 2018

(30) Foreign Application Priority Data
Jul. 19, 2018 (TW) 107125010

(51) Int. Cl. H05K 1/11; H01L 21/48; H01L 23/498; H05K 3/46; H05K 3/40

(52) U.S. Cl. CPC H05K 1/115; H01L 21/4857; H05K 3/4069; H01L 23/49822; H05K 3/4617; H01L 21/486

(57) ABSTRACT

A substrate structure includes a first circuit structure, a second dielectric layer, and a second circuit structure. The first circuit structure includes a first layer and a second layer. The first layer includes a first dielectric layer and a first circuit layer embedded in the first dielectric layer. The second layer is disposed below the first layer and includes a second circuit layer electrically connected to the first circuit layer. The second dielectric layer is disposed on the first circuit structure and has a first opening exposing a portion of the first circuit layer. The melting point of the second dielectric layer is lower than that of the first dielectric layer. The second circuit structure is disposed on the second dielectric layer and has a second opening connected to the first opening. The second circuit structure includes a third circuit layer electrically connected to the first circuit layer.

### CROSS-REFERENCE TO RELATED APPLICATION

This application claims priority to Taiwan Application Serial Number 107125010, filed Jul. 19, 2018, which is herein incorporated by reference.

### BACKGROUND

### Field of Invention

The present invention relates to a substrate structure and a manufacturing method thereof.

### Description of Related Art

In recent years, along with the rapid development of electronic technology and the evolution of the high-tech electronics industries, there are continually innovative electronic products which are more user-friendly and functional, and they are trending towards a lightweight, thin, short, and small design. It is common to have a circuit substrate disposed in these electronic products. The circuit substrate serves for loading one or more electronic components. However, the arrangement of the electronic components on the circuit substrate causes an increase in the load area. Therefore, how to embed the electronic components in the circuit substrate has become one of the current key technologies.

In the conventional technology, a laser drilling process is first performed to form an opening in a circuit substrate, and then an electronic component is disposed in the opening. However, a metal layer that serves as a laser drilling stop layer may absorb the thermal energy produced by the laser light and then conduct the thermal energy to the circuit and dielectric layer below the metal layer. In this way, the circuit below the metal layer is prone to flake off.

### SUMMARY

One aspect of the present invention is to provide a substrate structure comprising a first circuit structure, a second dielectric layer, and a second circuit structure. The first circuit structure includes a first layer and a second layer. The first layer includes a first dielectric layer and a first circuit layer. The first circuit layer is embedded in the first dielectric layer. The second layer is disposed below the first layer and includes a second circuit layer. The second circuit layer is electrically connected to the first circuit layer. The second dielectric layer is disposed on the first circuit structure and has a first opening exposing a portion of the first circuit layer. The second dielectric layer has a melting point lower than a melting point of the first dielectric layer. The second circuit structure is disposed on the second dielectric layer and has a second opening connected to the first opening. The second circuit structure includes a third circuit layer electrically connected to the first circuit layer.

In some embodiments of the present invention, the substrate structure further includes a built-up structure. The built-up structure is disposed below the first circuit structure. The built-up structure includes a first built-up layer. The first built-up layer includes a fourth circuit layer electrically connected to the second circuit layer.

In some embodiments of the present invention, the built-up structure further includes a second built-up layer disposed below the first built-up layer. The second built-up layer includes a fifth circuit layer electrically connected to the fourth circuit layer.

In some embodiments of the present invention, the substrate structure further includes a first conductive pad and a first solder mask layer. The first conductive pad is disposed on the second circuit structure, and the first conductive pad is electrically connected to the third circuit layer. The first solder mask layer covers the first conductive pad and has a first hole exposing a portion of the first conductive pad.

In some embodiments of the present invention, the substrate structure further includes a second conductive pad and a second solder mask layer. The second conductive pad is disposed below the first circuit structure and is electrically connected to the second circuit layer. The second solder mask layer covers the second conductive pad and has a second hole exposing a portion of the second conductive pad.

Another aspect of the present invention is to provide a manufacturing method of a substrate structure. The manufacturing method includes steps of: (i) forming a first circuit structure, in which the first circuit structure includes a first layer and a second layer. The first layer includes a first dielectric layer and a first circuit layer, in which the first circuit layer is embedded in the first dielectric layer. The second layer is disposed below the first layer and includes a second circuit layer, in which the second circuit layer is electrically connected to the first circuit layer; (ii) forming a pyrolysis layer on the first circuit structure, in which the pyrolysis layer has a melting point lower than a melting point of the first dielectric layer; (iii) forming a first metal layer on a laser drilling area of the pyrolysis layer; (iv) forming a preceding second circuit structure on the pyrolysis layer and the first metal layer; (v) in an orthogonal projection direction of the laser drilling area, performing a laser drilling process to the preceding second circuit structure and the pyrolysis layer so as to form a second circuit structure, a second dielectric layer, and a defective film, in which the second circuit structure includes a third circuit layer electrically connected to the first circuit layer, and the defective film is disposed between the first metal layer and the first circuit structure; and (vi) removing the first metal layer and the defective film.

In some embodiments of the present invention, the first metal layer to the pyrolysis layer has a thickness ratio of 2:1 to 3:1.

In some embodiments of the present invention, the first metal layer has a thickness of 15˜30 μm.

In some embodiments of the present invention, in the step (vi), the first metal layer and the defective film are removed by a stripping process.

In some embodiments of the present invention, the step (i) further includes substeps of: (a) providing a core layer, in which the core layer includes a core dielectric layer, a second metal layer disposed below the core dielectric layer, and a third metal layer disposed below the second metal layer; (b) forming the first layer of the first circuit structure below the third metal layer; (c) forming the second layer of the first circuit structure below the first layer; and (d) stripping off the core layer, thereby forming the first circuit structure.

It is to be understood that both the foregoing general description and the following detailed description are by examples, and are intended to provide further explanation of the invention as claimed.

### BRIEF DESCRIPTION OF THE DRAWINGS

FIG. 1 is a schematic sectional view of a substrate structure according to one embodiment of the present invention.

FIG. 2 to FIG. 8A are schematic sectional views at various stages of a manufacturing method of a substrate structure according to one embodiment of the present invention.

FIG. 8B is a detailed view of a region in a portion of FIG. 8A.

### DETAILED DESCRIPTION

In order to make the description of the present disclosure more detailed and complete, the following description of the aspects and the specific embodiments of the present disclosure are provided. However, this is not the only way in which the specific embodiments of the present disclosure are implemented or utilized. The embodiments disclosed below may be combined or substituted with each other in an advantageous situation, and other embodiments may be added to an embodiment without further description or explanation. In the following description, certain specific details are set forth in order to provide a thorough understanding of various embodiments of the disclosure. However, one skilled in the art will understand that the disclosure may be practiced without these specific details.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in one of the figures is turned over, elements described as being on the “lower” side of other elements would then be oriented on “upper” sides of the other elements. In addition, the spatially relative descriptors used herein may likewise be interpreted accordingly.

The embodiments of the present invention are disclosed as follow. However, it should be understood that these details of practice do not intend to limit the present invention.

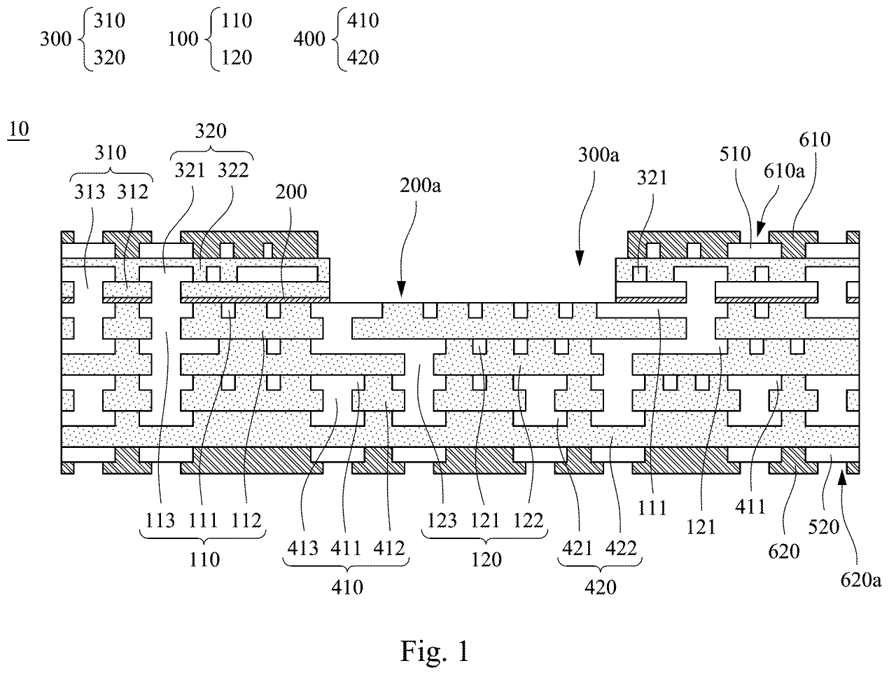

FIG. 1 depicts a schematic sectional view of a substrate structure 10 according to one embodiment of the present invention. The substrate structure 10 includes a first circuit structure 100, a second dielectric layer 200, and a second circuit structure 300.

The first circuit structure 100 includes a first layer 110 and a second layer 120. Specifically, the first layer 110 includes a first dielectric layer 112, a first circuit layer 111, and a first conductive contact 113. The first circuit layer 111 and the first conductive contact 113 are embedded in the first dielectric layer 112. In detail, an upper surface of the first circuit layer 111 is coplanar with an upper surface of the first dielectric layer 112. The first conductive contact 113 is in contact with the first circuit layer 111, while a bottom surface of the first conductive contact 113 is exposed out of the first dielectric layer 112. In some examples, the first circuit layer 111 includes any conductive material, such as copper, nickel, silver, or similar metal. In some examples, the first dielectric layer 112 includes an Ajinomoto Build-up Film (ABF), polyimide (PI), or a photoimageable dielectric (PID). In some examples, the first conductive contact 113 may be a metal column, and the metal column may include a conductive metal, such as copper, nickel, silver, or the like.

The second layer 120 is disposed below the first layer 110 and includes a third dielectric layer 122, a second circuit layer 121, and a second conductive contact 123. The second circuit layer 121 and the second conductive contact 123 are embedded in the third dielectric layer 122. In detail, the second circuit layer 121 is in contact with an exposed portion of the first conductive contact 113, such that the second circuit layer 121 is electrically connected to the first circuit layer 111. An upper surface of the second circuit layer 121 and an upper surface of the third dielectric layer 122 are coplanar. The second conductive contact 123 in contact with the second circuit layer 121, while a bottom surface of the second conductive contact 123 is exposed out of the third dielectric layer 122. In some examples, the second circuit layer 121 includes any conductive material, such as copper, nickel, silver, or similar metal. In some examples, the third dielectric layer 122 includes an Ajinomoto Build-up Film (ABF), polyimide (PI), or a photoimageable dielectric (PID). In some examples, the second conductive contact 123 may be a metal column, and the metal column includes a conductive metal, such as copper, nickel, silver, or the like.

The second dielectric layer 200 is disposed on the first circuit structure 100. As shown in FIG. 1, the second dielectric layer 200 has a first opening 200a, and a portion of the first circuit layer 111 is exposed from the first opening 200a. The second dielectric layer 200 has a melting point lower than a melting point of the first dielectric layer 112. In some examples, the second dielectric layer 200 includes an Ajinomoto Build-up Film (ABF), polyimide (PI) or a photoimageable dielectric (PID).

The second circuit structure 300 is disposed on the second dielectric layer 200. As shown in FIG. 1, the second circuit structure 300 has a second opening 300a connected to the first opening 200a. Specifically, the second circuit structure 300 includes a third layer 320 and a fourth layer 310. The third layer 320 is disposed on the second dielectric layer 200, and the fourth layer 310 is disposed between the third layer 320 and the second dielectric layer 200.

The third layer 320 includes a third circuit layer 321 and a fourth dielectric layer 322, and the fourth dielectric layer 322 covers the third circuit layer 321. The fourth layer 310 includes a fifth dielectric layer 312 and a third conductive contact 313. The third conductive contact 313 is embedded in the fifth dielectric layer 312. In detail, an upper surface of the third conductive contact 313 and an upper surface of the fifth dielectric layer 312 are coplanar. The third conductive contact 313 is in contact with third circuit layer 321, and the bottom of the third conductive contact 313 is exposed out of the fifth dielectric layer 312. The third conductive contact 313 penetrates through the second dielectric layer 200 and is in contact with the first circuit layer 111. Therefore, the third circuit layer 321 is electrically connected to the first circuit layer 111. In some examples, the third circuit layer 321 includes any conductive material, such as copper, nickel, silver, or similar metal. In some examples, the fourth dielectric layer 322 and the fifth dielectric layer 312 includes an Ajinomoto Build-up Film (ABF), polyimide (PI), or a photoimageable dielectric (PID). In some examples, the third conductive contact 313 may be a metal column, and the metal column includes a conductive metal, such as copper, nickel, silver, or the like. It is understood that although only a circuit layer (i.e., third circuit layer 321) is included in the second circuit structure 300 of the substrate structure 10 which is depicted in FIG. 1, the second circuit structure 300 may include two circuit layers or more than two circuit layers in other examples.

As shown in FIG. 1, a portion of the first circuit layer 111 is exposed from the first opening 200a and the second opening 300a, such that electrical components may be disposed in the first opening 200a and the second opening 300a for electrically connecting to the exposed portion of the first circuit layer 111.

In some examples, the substrate structure 10 further includes a built-up structure 400. The built-up structure 400 is disposed below the first circuit structure 100. Specifically, the built-up structure 400 includes a first built-up layer 410 and a second built-up layer 420. The second built-up layer 420 is disposed below the first circuit structure 100, and the first built-up layer 410 is disposed between the first circuit structure 100 and the second built-up layer 420.

The first built-up layer 410 includes a sixth dielectric layer 412, a fourth circuit layer 411, and a fourth conductive contact 413. The fourth circuit layer 411 and the fourth conductive contact 413 are embedded in the sixth dielectric layer 412. In detail, the fourth circuit layer 411 is in contact with the exposed portion of the second conductive contact 123, such that the fourth circuit layer 411 is electrically connected to the second circuit layer 121. An upper surface of the fourth circuit layer 411 and an upper surface of the sixth dielectric layer 412 are coplanar. The fourth conductive contact 413 is in contact with fourth circuit layer 411, and a bottom surface of the fourth conductive contact 413 is exposed out of the sixth dielectric layer 412. In some examples, the fourth circuit layer 411 includes any conductive material, such as copper, nickel, silver, or similar metal. In some examples, the sixth dielectric layer 412 includes an Ajinomoto Build-up Film (ABF), polyimide (PI), or a photoimageable dielectric (PID). In some examples, the fourth conductive contact 413 may be a metal column, and the metal column includes a conductive metal, such as copper, nickel, silver, or the like.

The second built-up layer 420 includes a seventh dielectric layer 422 and a fifth circuit layer 421. The fifth circuit layer 421 is embedded in the seventh dielectric layer 422. In detail, the fifth circuit layer 421 is in contact with the exposed portion of the fourth conductive contact 413, such that the fifth circuit layer 421 is electrically connected to the fourth circuit layer 411. An upper surface of the fifth circuit layer 421 and an upper surface of the seventh dielectric layer 422 are coplanar. In some examples, the fifth circuit layer 421 includes any conductive material, such as copper, nickel, silver, or similar metal. In some examples, the seventh dielectric layer 422 includes an Ajinomoto Build-up Film (ABF), polyimide (PI), or a photoimageable dielectric (PID).

In some examples, the substrate structure 10 further includes a first conductive pad 510 and a first solder mask layer 610. The first conductive pad 510 is disposed on the second circuit structure 300, and the first conductive pad 510 is electrically connected to the third circuit layer 321. The first solder mask layer 610 covers the first conductive pad 510 and has a first hole 610a exposing a portion of the first conductive pad 510. Similarly, in some examples, the substrate structure 10 further includes a second conductive pad 520 and a second solder mask layer 620. The second conductive pad 520 is disposed below the first circuit structure 100, and the second conductive pad 520 is electrically connected to the fifth circuit layer 421. the second solder mask layer 620 covers the second conductive pad 520 and has a second hole 620a exposing a portion of the second conductive pad 520. In some examples, the first conductive pad 510 and the second conductive pad 520 includes metal such as copper, nickel, silver, or the like. In some examples, the first solder mask layer 610 and the second solder mask layer 620 includes a green-color solder mask.

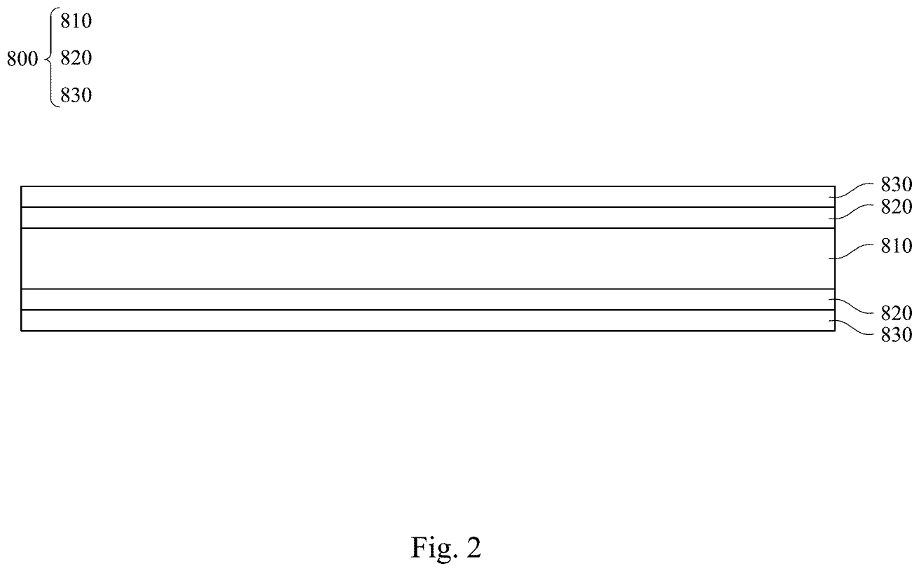

The present invention also provides a manufacturing method of the substrate structure 10. FIG. 2 to FIG. 8A are schematic sectional views illustrating a method of manufacturing a substrate structure 10 at various stages according to one embodiment of the present invention.

As shown in FIG. 2, a core layer 800 is provided. Specifically, the core layer 800 includes a core dielectric layer 810, two second metal layers 820, and two third metal layers 830. The second metal layers 820 are respectively disposed on opposite surfaces of the core dielectric layer 810, and the third metal layers 830 are respectively disposed on the second metal layer 820.

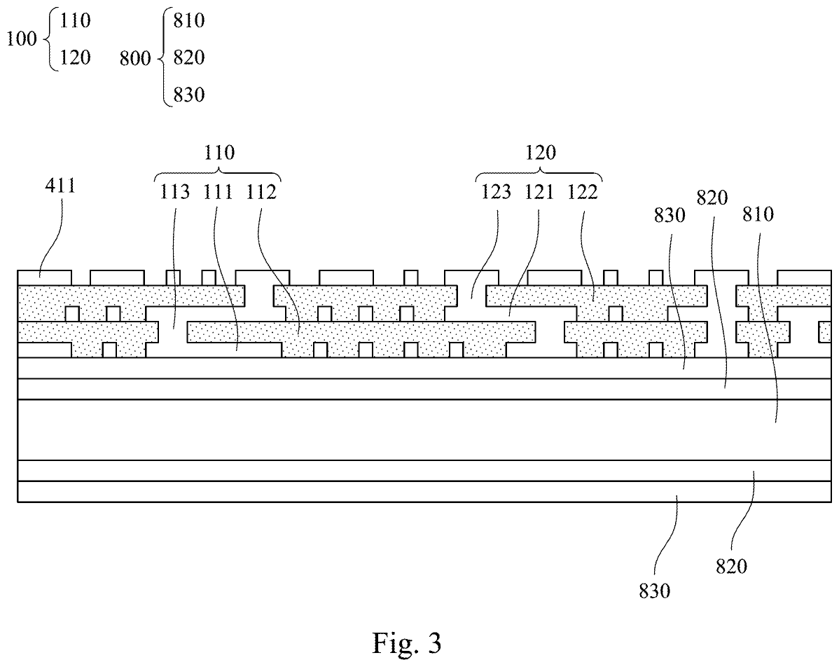

Next, as shown in FIG. 3, a first layer 110 of the first circuit structure 100 is formed on the third metal layer 830. Specifically, a first circuit layer 111 is formed on the third metal layer 830. Next, a first dielectric layer 112 covering the first circuit layer 111 is formed, and the first dielectric layer 112 has a via exposing a portion of the first circuit layer 111. Herein, the first circuit layer 111 may be formed by such as disposing an electroplating mask (not shown) on the surface of the core layer 800, followed by forming the first circuit layer 111 by an electroplating process with the third metal layer 830 of the core layer 800 serving as an electroplating seed layer. Subsequently, the electroplating mask is removed, and thus the fabrication of the first circuit layer 111 is completed, but not limited thereto.

Next, a second layer 120 of the first circuit structure 100 is formed on the first layer 110. Specifically, a second circuit layer 121 is formed on the first dielectric layer 112, and a first conductive contact 113 is formed in the via of the first dielectric layer 112. Then, a third dielectric layer 122 covering the second circuit layer 121 is formed, and the third dielectric layer 122 has a via exposing a portion of the second circuit layer 121.

Next, a fourth circuit layer 411 is formed on the third dielectric layer 122, and a second conductive contact 123 is formed in the via of the third dielectric layer 122.

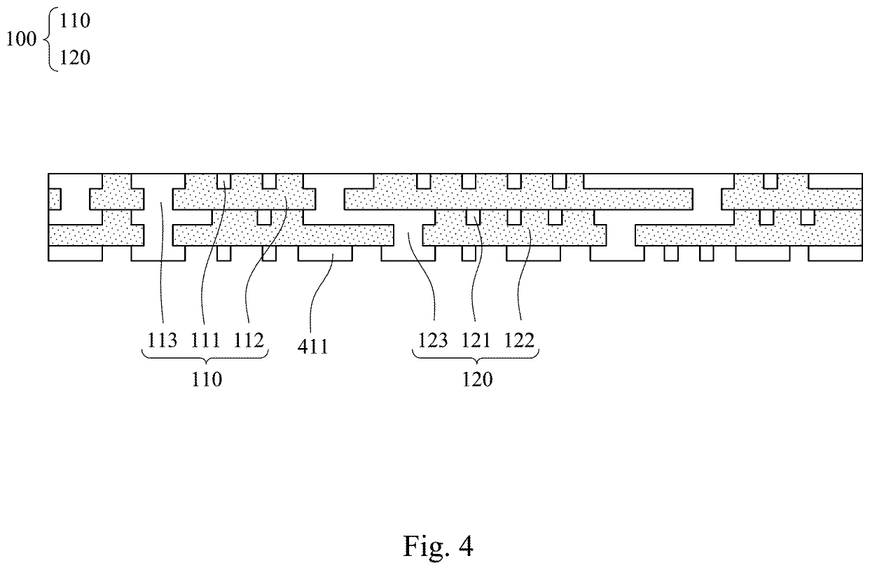

Next, as shown in FIG. 4, the structure as shown in FIG. 3 is flipped over, and then the core layer 800 is stripped off so as to expose the first circuit layer 111, such that the first circuit structure 100 is formed.

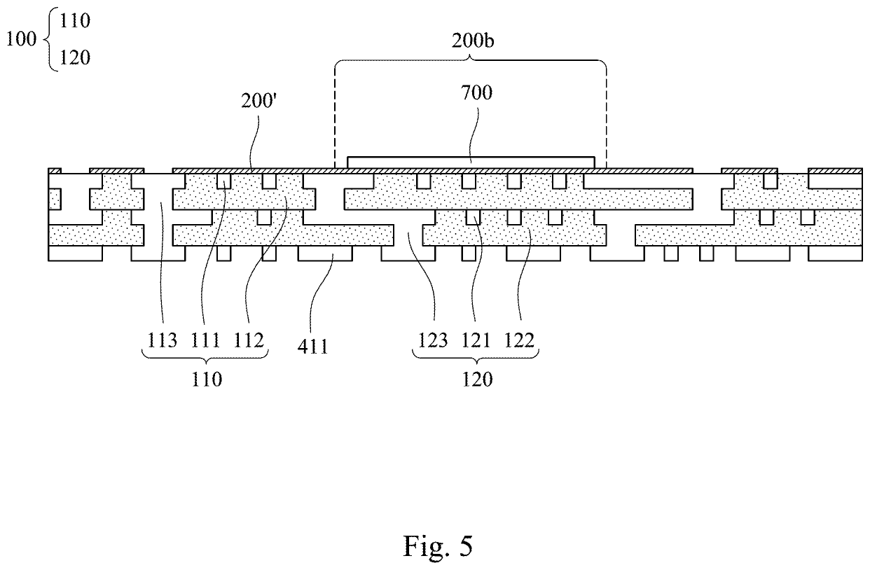

Next, as shown in FIG. 5, a pyrolysis layer 200′ is formed on the first circuit structure 100, and a first metal layer 700 is formed on the pyrolysis layer 200′. Specifically, the pyrolysis layer 200′ is formed on the first dielectric layer 112 and the first circuit layer 111. The pyrolysis layer 200′ has a via exposing a portion of the first circuit layer 111. In some examples, the pyrolysis layer 200′ includes an Ajinomoto Build-up Film (ABF), polyimide (PI), or a photoimageable dielectric (PID), and the pyrolysis layer 200′ has a melting point lower than a melting point of the first dielectric layer 112. It is noted that as the melting point of the pyrolysis layer 200′ is lower than the melting point of the first dielectric layer 112, some specific technical effects are provided, which will be described below. Moreover, the pyrolysis layer 200′ has a laser drilling area 200b, and the first metal layer 700 is disposed on the laser drilling area 200b of the pyrolysis layer 200′. In some examples, the first metal layer 700 includes a metal material, such as copper, palladium, nickel, silver, or the like. In some examples, the thickness ratio of the first metal layer 700 to the pyrolysis layer 200′ is ranged from 2:1 to 3:1. In some examples, the first metal layer 700 has a thickness of 15-30 μm, such as 18 μm, 21 μm, 24 μm, or 27 μm. In some examples, the pyrolysis layer 200′ has a thickness of 5-15 μm, such as 8 μm, 11 μm, or 14 μm.

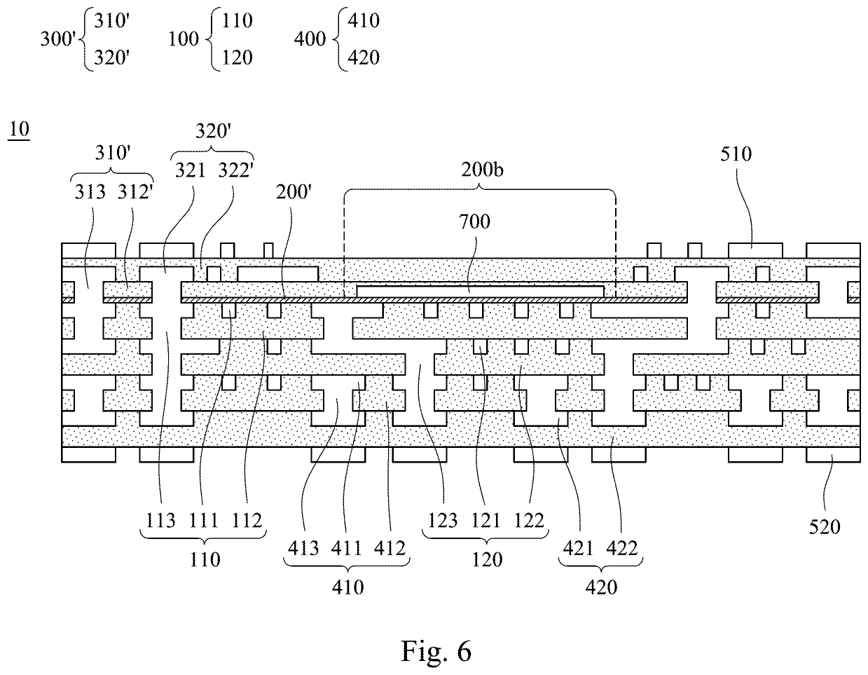

Next, as shown in FIG. 6, a preceding second circuit structure 300′ is formed on the pyrolysis layer 200′ and the first metal layer 700. Specifically, a dielectric layer 312′ is formed covering the pyrolysis layer 200′ and the first metal layer 700, and the dielectric layer 312′ has a via connected to the via of the pyrolysis layer 200′. Then, a third circuit layer 321 is formed on the dielectric layer 312′, and a third conductive contact 313 is formed in the via of the dielectric layer 312′ and the via of the pyrolysis layer 200′. Next, a dielectric layer 322′ covering the third circuit layer 321 is formed. It is noted that the abovementioned process may be repeated for forming a plurality of circuit layers stacked with each other on the first circuit structure 100 until reaching the desired layer number.

Next, a first built-up layer 410 and a second built-up layer 420 are formed below the first circuit structure 100. Specifically, a sixth dielectric layer 412 covering the fourth circuit layer 411 is formed, and the sixth dielectric layer 412 has a via exposing a portion of the fourth circuit layer 411. Then, a fifth circuit layer 421 is formed below the sixth dielectric layer 412, and a fourth conductive contact 413 is formed in the via of the sixth dielectric layer 412. Subsequently, a seventh dielectric layer 422 covering the fifth circuit layer 421 is formed. It is noted that the abovementioned process may be repeated for forming a plurality of circuit layers stacked with each other on the first circuit structure 100 until reaching the desired layer number.

Next, a first conductive pad 510 is formed on the dielectric layer 322′, and a second conductive pad 520 is formed below the seventh dielectric layer 422.

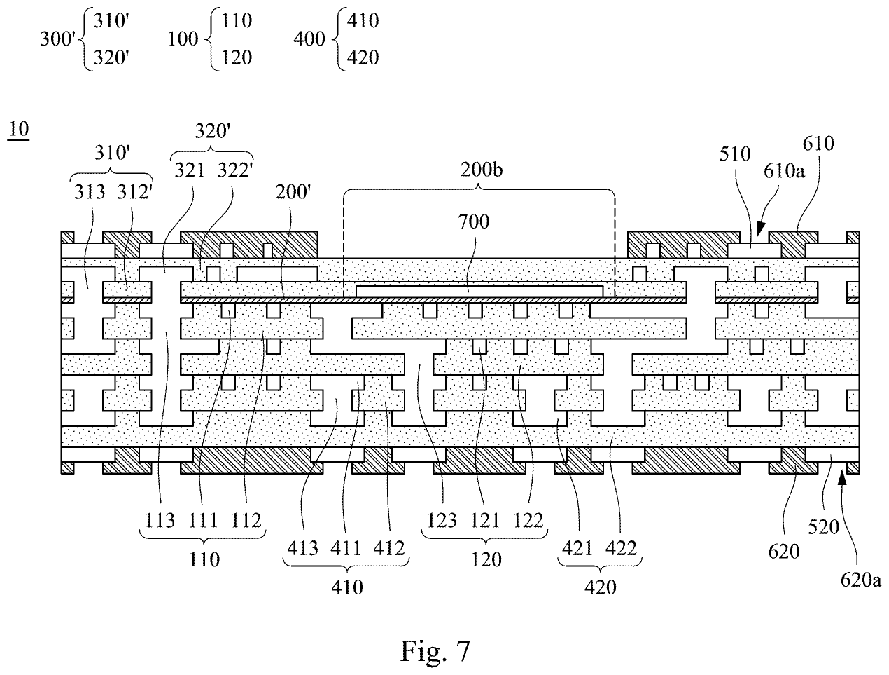

Next, as shown in FIG. 7, a first solder mask layer 610 covering the first conductive pad 510 is formed, and the first solder mask layer 610 has a first hole 610a exposing a portion of the first conductive pad 510. Then, a second solder mask layer 620 covering the second conductive pad 520 is formed, and the second solder mask layer 620 has a second hole 620a exposing a portion of the second conductive pad 520.

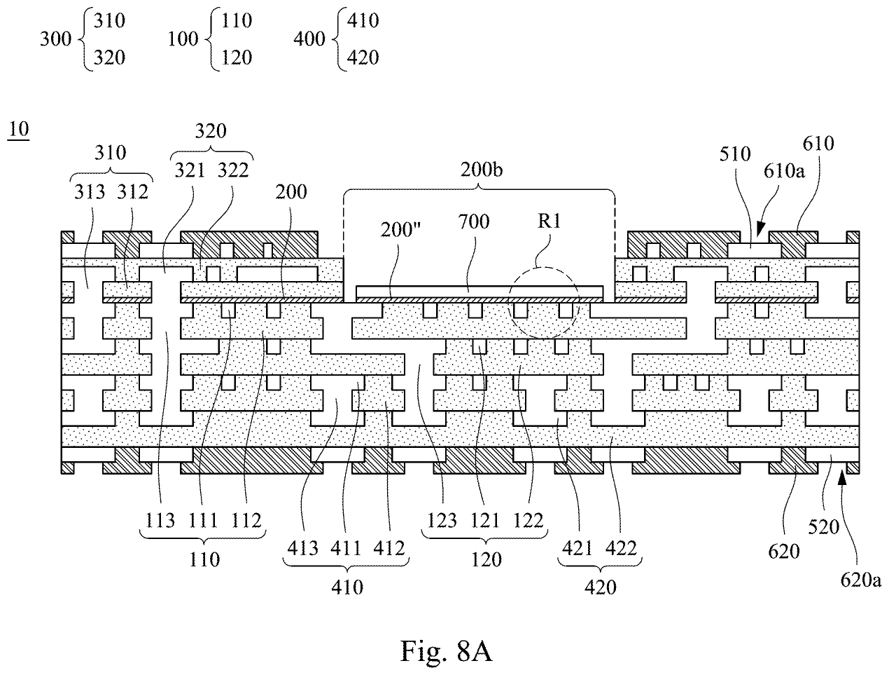

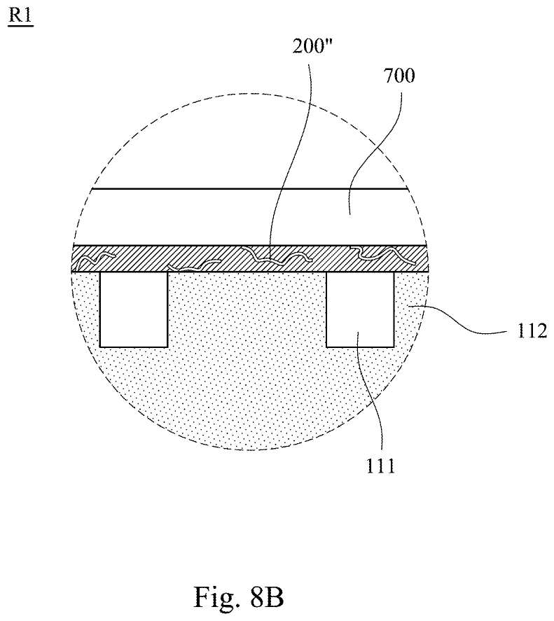

Next, a laser drilling process is performed on the preceding second circuit structure 300′ and the pyrolysis layer 200′ in an orthogonal projection direction of the laser drilling area 200b, thereby a structure as shown in FIG. 8A is formed. In detail, since the laser is not able to penetrate through a metallic material, such as copper, palladium, nickel, silver, or the like, and therefore the first metal layer 700 may serve as a laser drilling stop layer. After the laser drilling process, a portion of the dielectric layer 322′ and a portion of the dielectric layer 312′ in the laser drilling area 200b are removed, such that a second circuit structure 300 is formed. After the laser drilling process, in the laser drilling area 200b, a portion of the pyrolysis layer 200′ that is not covered by the first metal layer 700 is removed, and thereby a second dielectric layer 200 and a defective film 200″ that is covered by the first metal layer 700 are formed.

As described above, as the pyrolysis layer 200′ has a melting point lower than a melting point of the first dielectric layer 112, some specific technical effects are provided. Specifically, the first metal layer 700 which serves as a laser drilling stop layer absorbs the thermal energy produced by the laser, and then the thermal energy is conducted to the underlying pyrolysis layer 200′ and the first dielectric layer 112. Before the temperature of the first dielectric layer 112 reaches its melting point and undergoes pyrolysis, the temperature of the pyrolysis layer 200′ reaches its melting point and the pyrolysis layer 200′ undergoes pyrolysis to form a defective film 200″.

Reference is made to FIG. 8B, which depicts a detailed view of a region R1 in FIG. 8A. The defective film 200″ absorbs thermal energy and undergoes pyrolysis to form cracks which may prevent the conduction of thermal energy to the underlying first circuit layer 111 and the first dielectric layer 112. In this way, the issue of the flaking off circuit below the laser drilling stop layer may be prevented.

Next, the first metal layer 700 and the defective film 200″ are removed, and thereby the substrate structure 10 as shown in FIG. 1 is formed. Since there are cracks in the defective film 200″, and therefore the first metal layer 700 and the defective film 200″ can be removed more easily. In some examples, the first metal layer 700 and the defective film 200″ may be removed by a stripping process.

As disclosed in the abovementioned examples of the present invention, in the method of manufacturing the substrate structure 10 as disclosed herein, during the laser drilling process, the pyrolysis layer 200′ disposed below the first metal layer 700 may prevent the conduction of thermal energy to the underlying the first circuit layer 111 and the first dielectric layer 112. In this way, the issue of the flaking off circuit below the laser drilling stop layer may be prevented.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A substrate structure, comprising:
a first circuit structure, comprising:
a first layer comprising a first dielectric layer and a first circuit layer, wherein the first circuit layer is embedded in the first dielectric layer; and
a second layer disposed below the first layer and including a second circuit layer, wherein the second circuit layer is electrically connected to the first circuit layer;
a second dielectric layer disposed on the first circuit structure and having a first opening exposing a portion of the first circuit layer, wherein the second dielectric layer has a melting point lower than a melting point of the first dielectric layer, and the second dielectric layer has a pyrolysis temperature less than a pyrolysis temperature of the first dielectric layer; and
a second circuit structure disposed on the second dielectric layer and having a second opening connected to the first opening, wherein the second circuit structure comprises a third circuit layer electrically connected to the first circuit layer.

2. The substrate structure of claim 1, further comprising:
a built-up structure disposed below the first circuit structure, wherein the built-up structure comprises:
a first built-up layer comprising a fourth circuit layer, wherein the fourth circuit layer is electrically connected to the second circuit layer.

3. The substrate structure of claim 2, wherein the built-up structure further comprises a second built-up layer disposed below the first built-up layer, and the second built-up layer comprises a fifth circuit layer electrically connected to the fourth circuit layer.

4. The substrate structure of claim 1, further comprising:
a first conductive pad disposed on the second circuit structure, and the first conductive pad is electrically connected to the third circuit layer; and
a first solder mask layer covering the first conductive pad and having a first hole exposing a portion of the first conductive pad.

5. The substrate structure of claim 1, further comprising:
a second conductive pad disposed below the first circuit structure and is electrically connected to the second circuit layer; and
a second solder mask layer covering the second conductive pad and having a second hole that exposes a portion of the second conductive pad.

6. A manufacturing method of a substrate structure, comprising steps of:
(i) forming a first circuit structure, wherein the first circuit structure comprises:
a first layer comprising a first dielectric layer and a first circuit layer, wherein the first circuit layer is embedded in the first dielectric layer; and
a second layer disposed below the first layer and having a second circuit layer, wherein the second circuit layer is electrically connected to the first circuit layer;
(ii) forming a pyrolysis layer on the first circuit structure, wherein the pyrolysis layer has a melting point lower than a melting point of the first dielectric layer;
(iii) forming a first metal layer on a laser drilling area of the pyrolysis layer;
(iv) forming a preceding second circuit structure on the pyrolysis layer and the first metal layer;
(v) in an orthogonal projection direction of the laser drilling area, performing a laser drilling process to the preceding second circuit structure and the pyrolysis layer so as to form a second circuit structure, a second dielectric layer, and a defective film, wherein the second circuit structure comprises a third circuit layer electrically connected to the first circuit layer, and the defective film is disposed between the first metal layer and the first circuit structure; and
(vi) removing the first metal layer and the defective film.

7. The manufacturing method of claim 6, wherein the first metal layer and the pyrolysis layer have a thickness ratio of 2:1 to 3:1.

8. The manufacturing method of claim 6, wherein the first metal layer has a thickness of 15˜30 μm.

9. The manufacturing method of claim 6, wherein in the step (vi), the first metal layer and the defective film are removed by a stripping process.

10. The manufacturing method of claim 6, wherein the step (i) further comprises substeps of:
(a) providing a core layer, wherein the core layer comprises a core dielectric layer, a second metal layer disposed below the core dielectric layer, and a third metal layer disposed below the second metal layer;
(b) forming the first layer of the first circuit structure below the third metal layer;
(c) forming the second layer of the first circuit structure below the first layer; and
(d) stripping off the core layer, thereby forming the first circuit structure.
